(19) United States
(12) Patent Application Publication
(10) Pub. No.: US 2014/0090689 A1
(43) Pub. Date: Apr. 3, 2014

(54) PHOTOVOLTAIC MODULE COMPRISING CONDUCTORS IN THE FORM OF STRIPS

(71) Applicant: Commissariat A L'Energie Atomique Et Aux Energies Alternatives, Paris (FR)

(72) Inventors: Philippe VOARINO, Nice (FR); Paul LEFILLASTRE, Paris (FR)

(73) Assignee: Commissariat A L'Energie Atomique Et Aux Energies Alternatives, Paris (FR)

(21) Appl. No.: 14/097,681

(22) Filed: Dec. 5, 2013

Related U.S. Application Data
(63) Continuation of application No. PCT/FR2012/050958, filed on Apr. 30, 2012.

(30) Foreign Application Priority Data
Jul. 7, 2011 (FR) 11.56192

(51) Int. Cl. H01L 31/02; H01L 31/048

(52) U.S. Cl. CPC H01L 31/0201; H01L 31/048
USPC 136/246; 136/251; 438/66

(57) ABSTRACT

A photovoltaic module including a transparent upper plate and a lower plate, electrically insulating and sealed to each other to define a tight package; photovoltaic cells pressed between the upper and lower plates; at least two electric contacts arranged on at least a surface of each cell, at least one electric contact being in the form of a strip; and elements electrically connecting the contacts of each cell with the contacts of at least one adjacent cell. At least one strip of each cell is housed in a groove made in the plate in front or it, the groove is defined by: a depth between one quarter and three quarters of the thickness of the strip in a uncompressed state; a width greater than or equal to the width of the strip at 85° C.; and a length greater than or equal to the length of the strip at 85° C.

### FIELD OF THE INVENTION

The invention relates to the field of photovoltaic modules, and more specifically to photovoltaic modules having their photovoltaic cells electrically connected by conductive strips, said cells being encapsulated under a low pressure between two plates.

### BACKGROUND

A photovoltaic cell is a semiconductor device which converts an incident radiation, solar in the case in point, into an electric current by means of a PN junction.

More specifically, the generated electrons are collected by a network of narrow metal electrodes formed in the cell bulk in contact with the anode area(s) thereof, and conveyed by this network to one or several electrodes of larger dimensions, usually called “busbar” and flush with the cell surface.

To convey the electric current outside of the cell, an electric connector called “negative pole” is then placed into contact with each busbar. Similarly, one or several electric connectors are also provided in contact with the cathode area(s) of the cell, such electric connectors being usually called “positive poles”. The surface of a busbar most often being a rectilinear strip, an electric connector thus takes the form of a metal strip. In certain types of cells, one or several positive poles per cell also take the shape of a strip.

Further, a cell generally cannot, by itself, deliver an appropriate current and voltage for the operation of current electric equipment. In particular, a photovoltaic cell delivers a voltage lower than one volt and a current in the order of some ten milliamperes per square centimeter of a cell. Several cells should thus be connected in series and/or in parallel to output an appropriate current and/or voltage. It is then spoken of a “photovoltaic module”.

Besides, photovoltaic cells are fragile elements, most often intended to be used in difficult environmental conditions (rain, hail, etc.). Thus, photovoltaic cells are generally pressed between two protective plates, one at least being rigid and one at least being transparent at the front surface of the cell, for example, tempered glass plates, which provide both a protection against harsh environmental conditions and a sufficient rigidity for the handling and the assembly of photovoltaic modules.

Finally, still for reasons of protection of photovoltaic cells against environmental conditions, and especially against humidity and oxygen, which oxidizes the cells, said cells are placed in a non-oxidizing air-tight and impervious environment.

A first photovoltaic module manufacturing technique thus comprises welding the electric connectors to the cells, connecting the cells together according to a desired electric diagram, and then embedding the assembly in a material forming a sealed capsule, for example, in ethylene-vinyl acetate, and then pressing the cells thus embedded between two transparent rigid plates, for example, made of tempered glass.

However, the time for manufacturing a photovoltaic module according to this technique is very long, requires long heating phases to melt the capsule materials, many changes of equipment and many cleaning operations. This technique is thus expensive. Further, a degradation of the capsule can be observed in the long run, said capsule then no longer playing its function of protection against air and humidity.

A second “pressing” technique, described in document WO-A-2004/075304, has been developed to overcome these disadvantages.

Such a pressing technique essentially comprises pressing the cells and their connectors between two transparent, rigid, and insulating protective plates, by sealing the two plates together by means of a peripheral seal made of thermoplastic organic material to form an air-tight and impervious package. In parallel, on assembly, a neutral gas atmosphere under low pressure is created in the package. The electric conductors, which are sandwiched between the cells and the protective plates, are maintained in place on assembly by means of glue deposited on the plates, and of the pressure exerted by the protective plates on the connectors. Such a technique has thus enabled to very substantially decrease photovoltaic module manufacturing costs.

However, such a technique has a number of additional disadvantages relating to electric connectors in the form of strips.

First, the strips are not directly attached to the busbars but are placed thereon on assembly. A strip should thus be accurately aligned with its busbar, which thus requires using expensive equipment. Indeed, any misalignment results in placing a portion of the strip above a surface of the cell dedicated to the collection of an incident light flow, or “useful” surface. It should be noted that the useful surface of a photovoltaic cell is far from being the entire surface of a cell, particularly due to the presence of the collection electrode network. Thus, even a shading, which could be considered minute offhand, has a significant impact on the amount of current capable of being generated by a cell. As an example, for a photovoltaic cell having a 125-millimeter side length, capable of generating a maximum current density of 33 mA/cm², and comprising two busbars having a 2-millimeter width, a misalignment of one millimeter of the connector strips with respect to the busbars causes a 0.2-ampere drop of the current capable of being generated by the cell.

Then, during the use of the photovoltaic module, the means implemented to maintain the connector strips in place are not sufficient. Indeed, the photovoltaic cell may be submitted to very large thermal cycles. Further, standards have been developed on this subject and advocate for photovoltaic modules, photovoltaic cells, and their associated connectors, to be designed to resist thermal cycles from −40° C. to +85° C. (for example, standard NF EN 61215 and standard NF EN 61640). However, the thermal expansion coefficients of a cell, of the connector strips, and of the rigid plates are different, whereby these elements expand and contract differently. The strips pressed between the cells and the protective plates are submitted to very strong mechanical stress, which deforms them and makes them lose their initial rectilinear shape.

FIG. 1 is a top view of a photovoltaic cell 1 of a commercially available photovoltaic module manufactured according to the pressing technique. Cell 1 comprises two busbars 2, 3 having two rectilinear copper strips 4, 5 initially pressed thereon. After having been submitted to large thermal cycles, strips 4, 5 have deformed as illustrated. Not only do strips 4, 5 significantly shade cell 1, but they further only provide a very partial contact with busbars 2, 3.

Moreover, connector strips are submitted to non-homogeneous mechanical stress due to the surface unevennesses of protective plates, to the different cell thicknesses due to manufacturing tolerances, etc. Since the strips are not welded to the cells and are maintained in place on the busbars essentially by the pressure exerted by the protective plates, such mechanical stress may become critical. Now, so-called “low-frequency” deformations of glass plates achieved by conventional techniques have an amplitude in the order of 0.5 millimeter for a 300-millimeter length. In such a case, the quality of a photovoltaic module is thus partly random.

The above-mentioned disadvantages are strongly interdependent, the strip being submitted to non-homogeneous mechanical stress, which phenomenon is amplified by significant thermal cycles, thus causing a deformation and/or a misalignment of strips with respect to the busbars, thus generating a loss of electric contact resulting from the shading, which may entail a failure or a malfunction of a photovoltaic module.

### BRIEF DESCRIPTION OF THE INVENTION

The present invention aims at providing a photovoltaic module manufactured according to the pressing technology, enabling to accurately align and to maintain aligned connector strips and enabling these strips to remain in contact with the photovoltaic cells in case of strong unevennesses of the surfaces against which they are pressed and in case of thermal cycles of great amplitude.

For this purpose, the present invention aims at a photovoltaic module comprising:
an upper plate transparent to an incident radiation and a lower plate, electrically insulating and sealed to each other to define a tight package;
photovoltaic cells pressed between the upper and lower plates;
at least two electrically-conductive contacts arranged on at least one surface of each photovoltaic cell, at least one electric contact being in the form of a strip; and
elements electrically connecting the contacts of each cell with the contacts of at least one adjacent cell.

According to the invention, at least one strip of each cell is housed in a groove made in the plate in front of it, the groove being defined by:
a depth between one quarter and three quarters of the thickness of the strip in a uncompressed state;
a width greater than or equal to the width of the strip at 85° C.; and
a length greater than or equal to the length of the strip at 85° C.

In other words:
by housing a strip in a groove, an accurate alignment of the strip with a busbar may be simply achieved since the strip is guided and does not slide;
the groove has a depth smaller than the strip thickness and greater than the sum of the manufacturing tolerance relative to the strip thickness, of the manufacturing tolerance relative to the groove depth, and of the maximum amplitudes of the surface unevennesses of the protective plate. This guarantees that there is no clearance when the plate comprising the groove is pressed against a cell, and that the depth is sufficient to maintain the strip in place and to guide it as it expands and contracts. Further, since the groove depth is smaller than the strip width, the strip may be strongly pressed against the cell with a decrease in its thickness due to its crushing, which maintains the strip in place and ensures its contact with the cell. It should further be noted that the pressure exerted on the strip is more uniform than that exerted by a plate comprising no groove. This enables to attenuate, or even to eliminate the impact of surface unevennesses of the protective plate;
the groove has a thickness which enables it never to laterally compress the strip when the width thereof increases by expansion and thus avoids for the strip to fold and to lose contact with the cell; and
the groove has a length greater than the possible strip length after an expansion at a temperature of at least 85° C., which is the maximum temperature of standards NF EN 61215 and NF EN 61640. Thus, the strip is guided in its expansion by the groove and does not come out of it. With a shorter groove, the end of the strip which would come out of the groove under the effect of expansion would be likely to twist, which would make the strip come out of the groove.

According to an embodiment, the groove depth is substantially equal to half the thickness of the strip in the uncompressed state. It has thus been observed that this depth enables to obtain the above-described effects whatever the material forming the strips, which simplifies the design and the manufacturing of photovoltaic modules.

According to an embodiment, the photovoltaic module comprises cells aligned in a row, strips arranged on the surfaces of said cells being aligned and housed in a single groove extending along at least the total length of the aligned cells, which simplifies the manufacturing of the protective plate.

As a variation, with a photovoltaic module comprising cells aligned in a row, said module comprises strips of said cells, said strips being aligned and housed in a plurality of separate grooves extending along all or part of the length of each cell. In particular, adjacent grooves are spaced apart by a distance shorter than the length of a space separating adjacent cells by at least a value equal to a linear expansion of the material forming the strips, induced by a temperature variation from 25° C. to 85° C.

According to an embodiment of the invention, a surface of the plate at the bottom of the groove comprises a micron-scale texturing, particularly a network of rounded micron-scale prisms. This for example enables to trap air or a gas between the strip and the protective plate, and thus to create a refraction index difference between the two elements, and as thereby, to redirect the incident light onto the cells by refraction and reflection. The spaces of the texturing opposite to the strip may also be filled with another material, which enables to optimally adapt the indexes.

More generally, the texturing implements an optical function for the incident radiation selected from among refraction, reflection, scattering, diffraction, and wave guiding.

More specifically, the texturing is a network of prisms which enables to deviate part of the light incident on the groove onto the useful surface of the photovoltaic cell. A nanoscale diffraction network may also be used for this purpose.

According to an embodiment, at least two strips are arranged on each surface of each cell, the strips of the first surface being arranged on a negative pole of the cell, and the connection elements connect the strips of the first surface of a cell respectively to the strips of the second surface of an adjacent cell.

The invention also concerns a method for manufacturing a photovoltaic module of the above-mentioned type, comprising:
forming grooves in one and/or the other of the upper plate and of the lower plate, the grooves having:
   a depth between one quarter and three quarters of the thickness of the strip in a uncompressed state;
   a width greater than or equal to the width of the strip at 85° C.; and
   a length greater than or equal to the length of the strip at 85° C.,
stacking the first plate, the cells, and the electric contacts, and the second plate, each groove housing a strip; and
sealing the stack thus formed by gluing or by pressing or by welding.

Particularly, the grooves are formed by laser etching.

### BRIEF DESCRIPTION OF THE DRAWINGS

The present invention will be better understood on reading of the following description provided as an example only in relation with the accompanying drawings, where the same reference numerals designate the same or functionally similar elements, among which:

FIG. 1 is a simplified top view of a photovoltaic cell of a photovoltaic module of the state of the art, with deformed connector strips due to a large number of thermal cycles;

FIG. 2 is a simplified top view of two series-connected adjacent cells of a photovoltaic module according to the invention;

FIG. 3 is a simplified cross-section view of the module of FIG. 2 along plane A-A;

FIG. 4 is a simplified cross-section view of the module of FIG. 2 along plane B-B;

FIG. 5 is a simplified cross-section view of a module according to another variation of the invention wherein the strips in front of a cell are connected to the strips at the rear surface of another adjacent cell;

FIG. 6 is a view of a detail of FIG. 4 corresponding to the area in dotted lines;

FIG. 7 is a simplified top view illustrating continuous grooves of a protective plate;

FIG. 8 is a simplified top view illustrating discontinuous grooves of a protective plate;

FIG. 9 is a cross-section view of another variation of micron-scale prisms arranged at the bottom of the grooves of a photovoltaic module according to the invention; and

FIG. 10 is a simplified cross-section view of a photovoltaic module according to the invention where only part of the connector strips are housed in grooves of the protective plates, for example, the upper strips.

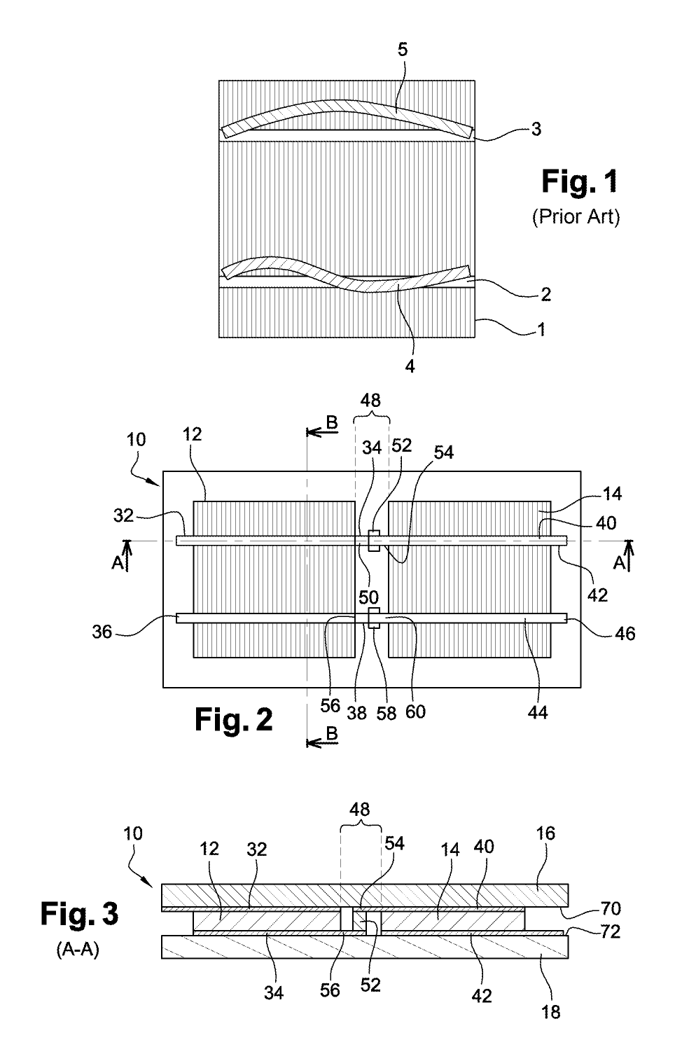

### DETAILED DESCRIPTION

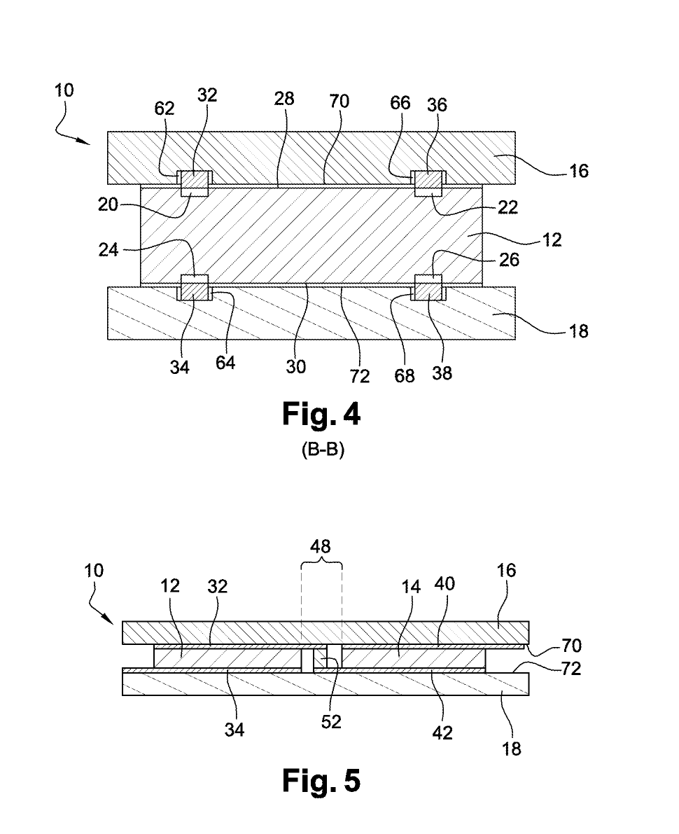

A photovoltaic module 10 according to the invention is illustrated in FIGS. 2 to 4.

Module 10 comprises identical homojunction photovoltaic cells 12, 14, two in the example illustrated in FIGS. 2 to 4. Photovoltaic cells 12, 14 are pressed between a transparent upper protective plate 16, or “front” plate, and a lower protective plate 18, or “back” plate. Protective plates 16, 18 are rigid and electrically insulating, and are for example made of tempered glass. Plates 16, 18 are sealed to each other by means of a seal (not shown) to define an air-tight and impervious inner space, said space being filled with a neutral gas, for example, argon, and under a low pressure lower than 500 millibars, and preferably a pressure lower than 300 millibars.

Each photovoltaic cell 12, 14 further comprises two busbars 20, 22, 24, 26 on each of its surfaces, the two busbars 20, 22 of upper surface 28 of the cell for example corresponding to anode bars of the cell, and the two busbars 24, 26 of lower surface 30 of the cell being cathode bars of the cell.

A conductive strip 32-44 of rectangular cross-section, for example, made of copper, or of a copper-plated welding material, is further compressed on each busbar 20-22 by protective plates 16, 18. Strips 32-44 are for example identical and form the cell connectors for collecting the current generated by the cell.

Cells 12, 14 are spaced apart from one another by connection areas 48 having connection elements 50-60 electrically connecting the cells in series arranged therein. For example, the elements of series connection of two adjacent cells 12, 14 comprise ends 50, 56 of lower strips 34, 38 of cell 12 which extend in connection area 48 separating the two cells 12, 14, two conductive elements 52, 58 respectively pressed on ends 50, 56 of the lower strips, and ends 54, 60 of upper strips 40, 44 of cell 14 which extend in connection area 48 and which are pressed on conductive pieces 52, 58.

Reference will advantageously be made to application WO 2004/0753304 for examples of connection elements, of seals, of busbar and connector strip arrangements, the invention being likely to apply to any of the embodiments described in this document, it being understood that a difference therewith is that the invention considers another way of maintaining the connector strips on the busbars.

According to the invention, each strip 32-44 is housed in a groove 62-68 formed, for example by laser etching, within internal surfaces 70, 72 of protective plates 16, 18.

The groove may also be formed by molding, by chemical etching, or by sawing.

FIG. 5 is a simplified cross-section view of a variation which differs from the foregoing in that upper strips 32, 36 of cell 12 are respectively connected to lower strips 42, 46 of cell 14.

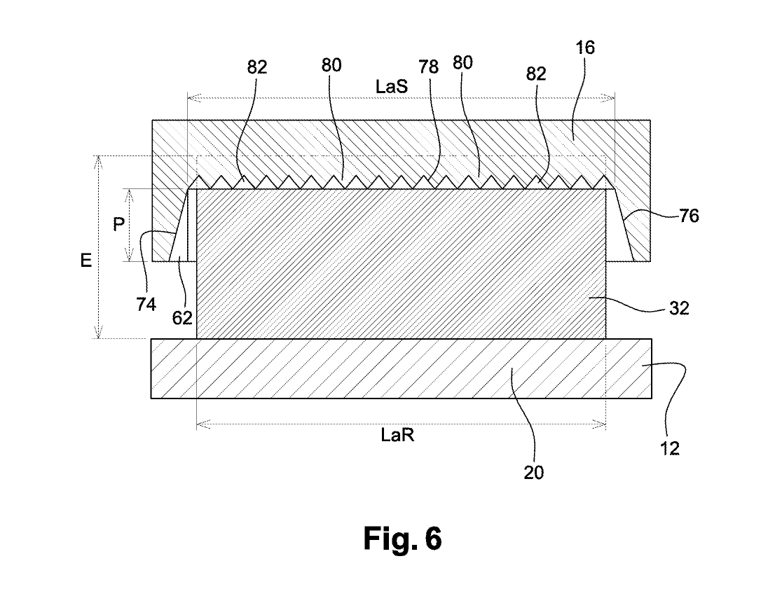

Referring to FIG. 6, which is an enlarged view of a groove 62 and of a strip 32, depth P of a groove is defined according, in particular, to thickness E of the strip housed by the groove, thickness E being the thickness of the uncompressed strip, illustrated in dotted lines in FIG. 5. During the assembly of module 10, protective plates 16, 18 are pressed on the photovoltaic cells to form a mechanically rigid assembly, the stack thus formed being maintained in the pressed state by a hardened seal and/or by mechanical fastening systems. The pressure exerted by protective plates 16, 18 thus also results in pressing strips 32-34 against cells 12, 14, which maintains the strips in place and compresses them.

Depth P is sufficient for the strip to remain housed in the groove, for example, in case of a shock, and to guide the strip during its expansion/contraction due to temperature variations. Further, depth P is smaller than thickness E of the uncompressed strip to ascertain that the bottom of the groove presses on the strip, and presses it against a cell. For a same groove geometry and a same strip geometry, the pressure however differs according to the thermomechanical properties of the material forming the strip, and especially to its Young's modulus and to its heat capacity, etc. The groove depth is thus advantageously also optimized according to the thermomechanical properties of the strip.

Further, the pressure exerted on the strip is also selected so that the strip follows the surface unevennesses of the protective plate and of the cell between which the strip is interposed.

It has thus been observed that a depth P of the groove between one quarter and three quarters of thickness E of the strip in a uncompressed state, and advantageously substantially equal to half uncompressed thickness E, allows a maintaining in place and a high-quality guiding for a great variety of materials forming the strips.

The groove may however be deeper. The manufacturing tolerances relative to thickness E of the strip, the manufacturing tolerance relative to the groove depth, the thermo-mechanical properties of the strip and the local flatness of the plate are then advantageously taken into account to ascertain that the strip always remains pressed against the cell, whatever the temperature.

Preferably, the groove is etched by using a technique which controls in real time, by means of an optical system, for example, the local flatness of the etching of the protective plate, which enables to control the groove etching in depth and thus to obtain a controlled groove depth. This results in decreasing or even in suppressing surface unevennesses of the plates.

Width LaS of the groove is selected to be greater, and preferably slightly greater, than maximum width LaR that a strip can take during a thermal cycle, so that no compression is ever exerted on the strip by lateral walls 74, 76 of the groove. It should be noted that width LaS of the groove thus depends on the maximum temperature that the strip is supposed to encounter in operation. Since the 85° C. temperature corresponds to a maximum temperature generally observed, the maximum width of the strip is thus defined for this temperature, although another temperature may be used as a basis for the determination of the geometry, length, width, and depth, of the groove. Width LS of the groove may also take into account the manufacturing tolerance relative to width LaR of the strip to guarantee that for any strip, there never is any compression thereof

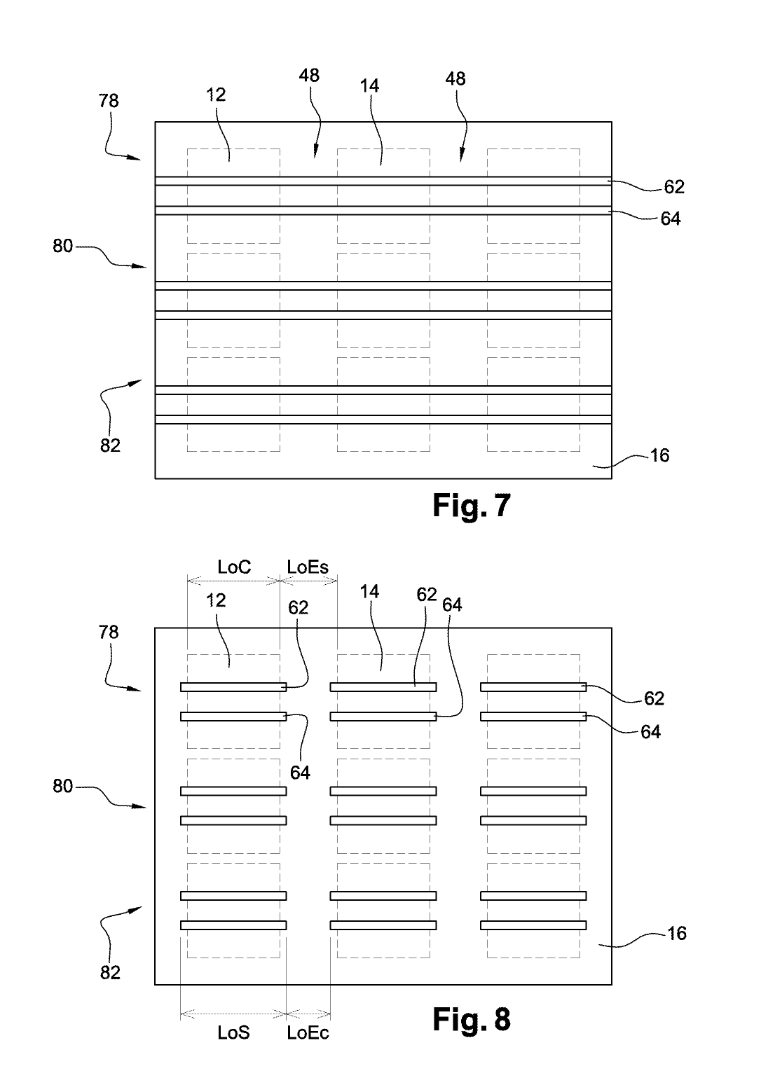

According to a first variation of the invention illustrated in FIG. 7, continuous grooves 62, 64 are formed along the length of the protective plates, each groove thus housing the aligned strips of a row 78, 80, 82 of photovoltaic cells. The grooves are particularly present along the entire cell length as well as between areas 48 separating said cells. This provides a sufficient length to guide and house the strips at the 85° temperature.

According to a second variation of the invention illustrated in FIG. 8, for each strip alignment of a row 78, 80, 82, discontinuous grooves are formed along the length of the protective plates, especially to avoid large rupture areas. Each groove is thus formed of aligned groove segments 62, 64 intended to house the cell strips.

Each groove segment has a length LoS sufficient to guide and house the strips after their expansion under the effect of high temperatures, and particularly a sufficient length to guide and house the strips and the maximum temperature encountered in use, advantageously a length sufficient to guide and house the strips at the 85° C. temperature. For example, a copper strip, which has an original length Lₒ, defined at temperature 25° C. equal to 320 millimeters, undergoes an expansion ΔL of its length by 160 micrometers at 85° C. Length LoS of a groove segment is thus, in this case, greater than the sum of length LoC of a cell and of its expansion ΔL.

Advantageously, an additional margin M is provided to ease the positioning of a strip in the groove segment on assembly of the photovoltaic module, for example, a 500-micrometer margin. Length LoS of the groove is then greater than or equal to the sum of length LoC, of expansion ΔL, and of margin M. The length of spacing LoEc between two consecutive aligned groove segments is then equal to the difference between length LoEs of the spacing of two consecutive cells in a row and of length LoS of the groove segments.

Of course, it is possible to combine continuous grooves and discontinuous segments in a same photovoltaic module.

Referring back to FIG. 6, lateral walls 74, 76 of the grooves optionally have a flared profile enabling an easy insertion of the strips into the grooves.

Optionally, the bottom of the grooves implements an optical function which enables to redirect light by obtaining a significant variation of refraction indexes towards the useful surface of the cells, and particularly outside of busbars. This enables to minimize reflection losses, which may amount to up to 4% of the incident flow on a cell of 125*125 square millimeters provided with two strips having a 2-millimeter width.

To achieve this, a micron-scale texturing is achieved on surface 78 of the plate at the bottom of groove 62, and more specifically a regular network of micron-scale patterns 80. Thereby, air or a gas is trapped in spaces 82 defined by the texturing. As a variation, spaces 82 are advantageously filled with the strip material, which enables to optimally adapt the refraction indexes. The size of the texturing patterns is smaller than 200 micrometers, preferably smaller than or equal to 50 micrometers, to avoid risking a low-frequency unevenness and thus a local curving of the strip.

In FIG. 6, micron-scale pattern network 80 is a micron-scale prism network.

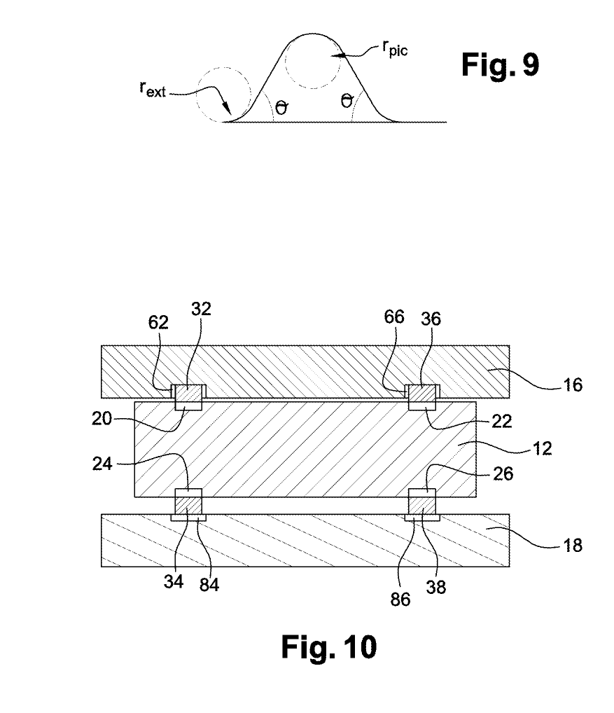

Advantageously, micron-scale pattern network 80 is a network of rounded micron-scale prisms, as illustrated in FIG. 9. For example, rounded prisms having a peak radius r_{pic} of 2.5 micrometers, an external radius rₑₓₜ of 5 micrometers and a prism angle θ of 43° C. enable to recover at least 0.2% of the total flow incident on the cell, which corresponds to a current density of 0.07 mA/cm² for a cell generating a maximum current density of 33 mA/cm².

Advantageously, groove bottom micron-scale pattern network 80 may also be designed to implement an optical scattering function or an optical diffraction function. In this case, part of the incident flow on the groove bottom is deviated towards the useful surface of a cell for its absorption, and this, with no additional structure, for example, assembled above the plate and shading the cell.

Finally, the network may be covered with a reflective layer to redirect light towards the upper area so that it can be reflected again towards the useful surface of the cell.

The grooves may be formed according to different techniques according to the materials forming the protective plates, and for example by:
an etching by evaporation by means of a CO₂ laser, which provides a rough surface state of the grooves;
an ablation etching by means of a femto-second laser, which provides a smooth surface state of the grooves;
an etching by molecular bond breakage by means of an Excimer laser;
a punching or a mechanical abrasion;
a thermoforming or a molding on manufacturing of the protective plates.

It should be understood that in the drawings, the sizes of the strips, of the grooves and of the busbars have been exaggeratedly enlarged for a better understanding.

In the described embodiments, all connector strips are housed in grooves. As a variation, as illustrated in FIG. 10, only part of the strips, for example, the strips on the upper cell surface, are housed in grooves. The other strips are assembled conventionally, for example, on adhesive strips 84, 86 formed on the corresponding protective plate.

Similarly, homo-junction photovoltaic cells have been described. The invention applies to any type of photovoltaic cell, for example, single-faced cells, two-faced cells, homojunction cells, heterojunction cells, P-type cells, N-type cells, . . .

1. A photovoltaic module comprising:
an upper plate transparent to an incident radiation and a lower plate, electrically insulating and sealed to each other to define a tight package;
photovoltaic cells pressed between the upper plate and the lower plate;
at least two electrically-conductive contacts arranged on at least one surface of each photovoltaic cell, at least one electric contact being in the form of a strip; and
elements electrically connecting the contacts of each cell with the contacts of at least one adjacent cell;
wherein at least one strip of each cell is housed in a groove made in the plate in front of it, the groove being defined by:
a depth between one quarter and three quarters of the thickness of the strip in a uncompressed state;
a width greater than or equal to the width of the strip at 85° C.; and
a length greater than or equal to the length of the strip at 85° C.

2. The photovoltaic module of claim 1, wherein the depth of the groove is substantially equal to half the thickness of the strip in the uncompressed state.

3. The photovoltaic module of claim 1, wherein it comprises cells aligned in a row, strips arranged on the surfaces of said cells being aligned and housed in a single groove extending along at least the total length of the aligned cells.

4. The photovoltaic module of claim 1, wherein it comprises cells aligned in a row, strips arranged on the surfaces of said cells being aligned and housed in a plurality of separate grooves extending along all or part of the length of each cell.

5. The photovoltaic module of claim 4, wherein adjacent grooves are spaced apart by a distance shorter than the length of a space separating adjacent cells by at least a value equal to a linear expansion of the material forming the strips, induced by a temperature variation from 25° C. to 85° C.

6. The photovoltaic module of foregoing claim 1, wherein a surface of the plate at the bottom of the groove comprises a micron-scale texturing.

7. The photovoltaic module of claim 6, wherein the texturing implements an optical function for the incident radiation selected from among refraction, reflection, scattering, diffraction, and wave guiding.

8. The photovoltaic module of claim 6, wherein the texturing is a prism network.

9. The photovoltaic module of claim 7, wherein the texturing is a prism network.

10. The photovoltaic module of claim 1, wherein at least two strips are arranged on each surface of each cell, the strips of the first surface being arranged on a positive pole of the cell, and the strips of the second surface being arranged on a negative pole of the cell, and wherein the connection elements connect the strips of the first surface of a cell respectively to the strips of the second surface of an adjacent cell.

11. A method of manufacturing a photovoltaic module comprising:
an upper plate transparent to an incident radiation and a lower plate, electrically insulating and sealed to each other to define a tight package;
photovoltaic cells pressed between the upper plate and the lower plate;
at least two electrically-conductive contacts arranged on at least one surface of each photovoltaic cell, at least one electric contact being in the form of a strip; and
elements electrically connecting the contacts of each cell with the contacts of at least one adjacent cell;
wherein it comprises:
forming grooves in one and/or the other of the upper plate and of the lower plate, the grooves having:
a depth between one quarter and three quarters of the thickness of the strip in a uncompressed state;
a width greater than or equal to the width of the strip at 85° C.; and
a length greater than or equal to the length of the strip at 85° C.,
stacking the first plate, the cells, and the electric contacts, and the second cell, each groove housing a strip;
sealing the stack thus formed by gluing or by pressing or by welding.

12. The method of manufacturing a photovoltaic module of claim 11, wherein the grooves are formed by laser etching.
